(19) United States
(12) Patent Application Publication
(10) Pub. No.: US 2019/0119815 A1
(43) Pub. Date: Apr. 25, 2019

(54) SYSTEMS AND PROCESSES FOR PLASMA FILTERING

(71) Applicant: Applied Materials, Inc., Santa Clara, CA (US)

(72) Inventors: Soonam Park, Sunnyvale, CA (US); Toan Q. Tran, San Jose, CA (US); Nikolai Kalnin, Belmont, CA (US); Dmitry Lubomirsky, Cupertino, CA (US); Akhil Devarakonda, San Jose, CA (US)

(73) Assignee: Applied Materials, Inc., Santa Clara, CA (US)

(21) Appl. No.: 16/167,074

(22) Filed: Oct. 22, 2018

Related U.S. Application Data
(60) Provisional application No. 62/576,379, filed on Oct. 24, 2017.

(51) Int. Cl. C23C 16/455; H01L 21/3065; H01L 21/311; H01L 21/02

(52) U.S. Cl. CPC C23C 16/45565; H01L 21/02315; H01L 21/31116; H01L 21/3065

(57) ABSTRACT

Systems and methods may be used to enact plasma filtering. Exemplary processing chambers may include a showerhead. The processing chambers may include a substrate support. The processing chambers may include a power source electrically coupled with the substrate support and configured to provide power to the substrate support to produce a bias plasma within a processing region defined between the showerhead and the substrate support. The processing systems may include a plasma screen coupled with the substrate support and configured to substantially eliminate plasma leakage through the plasma screen. The plasma screen may be coupled with electrical ground.

### CROSS-REFERENCE TO RELATED APPLICATIONS

This application claims a priority to and benefits of U.S. Provisional Patent Application No. 62/576,379, filed Oct. 24, 2017, the contents of which are hereby incorporated by reference in their entirety for all purposes.

### TECHNICAL FIELD

The present technology relates to semiconductor systems, processes, and equipment. More specifically, the present technology relates to systems and methods for filtering plasma within a processing chamber.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Systems and methods may be used to enact plasma filtering. Exemplary processing chambers may include a showerhead. The processing chambers may include a substrate support. The processing chambers may include a power source electrically coupled with the substrate support and configured to provide power to the substrate support to produce a bias plasma within a processing region defined between the showerhead and the substrate support. The processing systems may include a plasma screen coupled with the substrate support and configured to substantially eliminate plasma leakage through the plasma screen. The plasma screen may be coupled with electrical ground.

In some embodiments, the plasma screen may include an annular component extending radially outward from the substrate support. The plasma screen may be characterized by a first thickness about an interior radius of the plasma screen, and the plasma screen may be characterized by a second thickness less than the first thickness about an exterior radius of the plasma screen. The plasma screen may define a plurality of apertures through the plasma screen. The plurality of apertures may be defined within a region of the plasma screen characterized by the second thickness. Each aperture of the plurality of apertures may be characterized by a profile including a taper at least partially extending through the plasma screen. The plasma screen may define at least about 500 apertures through the plasma screen. Each aperture of the plurality of apertures may be characterized by a diameter of less than or about 0.25 inches. A gap may be maintained between a radial edge of the plasma screen and sidewalls of the semiconductor processing chamber. The plasma screen may be maintained electrically isolated from an electrostatic chuck portion of the substrate support electrically coupled with the power source.

The present technology also encompasses additional semiconductor processing chambers. The chambers may include a chamber sidewall. The chambers may include a showerhead. The chambers may also include a substrate support, and the substrate support may define a processing region of the semiconductor processing chamber with the showerhead and the chamber sidewall. The substrate support may include an electrically conductive puck. The substrate support may be moveable from a first vertical position within the processing region to a second vertical position within the processing region proximate the showerhead. The chambers may include a power source electrically coupled with the electrically conductive puck. The power source may be adapted to provide energy to the electrically conductive puck to form a bias plasma within the processing region. The chambers may also include a plasma screen coupled with the substrate support along a circumference of the substrate support. The plasma screen may extend radially outward toward the chamber sidewall, and the plasma screen may be maintained at electrical ground.

In some embodiments the plasma screen may be characterized by an interior radius and an exterior radius. The plasma screen may be characterized by an internal radius defined at a boundary between an interior region and an exterior region of the plasma screen. The plasma screen may define a plurality of apertures within the exterior region of the plasma screen and extending about the plasma screen. The plasma screen may be coupled at an exterior edge of the substrate support along the interior region of the plasma screen. The substrate support may include an edge ring circumscribing the substrate support. The edge ring may be seated on the interior region of the plasma screen. The edge ring may be quartz. The plasma screen may be characterized by a first thickness within the interior region. The plasma screen may be characterized by a second thickness within the exterior region, and the plasma screen may define a ledge at the internal radius. The chambers may include a liner extending along the chamber sidewall from a position proximate the showerhead to a location substantially coplanar to the plasma screen when the substrate support is in the second vertical position. The plasma screen may be coated on a first surface facing the showerhead.

The present technology may also encompass methods of reducing sputtering during semiconductor processing. The methods may include forming a bias plasma of a precursor within a processing region of a semiconductor processing chamber. The methods may include directing plasma effluents by the bias plasma to a substrate positioned on a substrate support within the semiconductor processing chamber. The methods may also include extinguishing plasma effluents with a plasma screen coupled about an exterior of the substrate support. The plasma screen may reduce contamination from sputtering of chamber components by greater than about 5%.

Such technology may provide numerous benefits over conventional systems and techniques. For example, plasma screens according to the present technology may eliminate plasma species from the processing region of the chamber. Additionally, substrate supports of the present technology may incorporate the plasma screen with plasma generating components on the substrate support. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to embodiments of the present technology.

FIG. 2 shows a schematic cross-sectional view of an exemplary processing chamber according to embodiments of the present technology.

FIG. 3 shows a schematic cross-sectional view of an exemplary processing chamber according to embodiments of the present technology.

FIG. 4 shows a schematic top plan view of an exemplary plasma screen according to embodiments of the present technology.

FIGS. 5A-5E illustrate schematic cross-sectional views of exemplary apertures that may be formed in a plasma screen according to embodiments of the present technology.

FIG. 6 illustrates exemplary operations in methods according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The present technology includes systems and components for semiconductor processing of small pitch features. As line pitch is reduced, standard lithography processes may be limited, and alternative mechanisms may be used in patterning. Conventional technologies have struggled with these minimal patterning and removal operations, especially when exposed materials on a substrate may include many different features and materials, some to be etched and some to be maintained.

Atomic layer etching is a process that utilizes a multiple-operation process of damaging or modifying a material surface followed by an etching operation. The etching operation may be performed at chamber conditions allowing the modified material to be removed, but limiting interaction with unmodified materials. This process may then be cycled any number of times to etch additional materials. Some chambers available can perform both operations within a single chamber. The modification may be performed with a bombardment operation at the substrate level, followed by a remote plasma operation to enhance etchant precursors capable of removing only the modified materials.

During the modification operation, a wafer-level plasma may be formed within the processing region. For example, a bias plasma may be formed from the substrate support, which may form a plasma of a precursor within a processing region. The plasma may direct ions to the surface of the substrate. The bias plasma may be a capacitively-coupled plasma, which may produce plasma effluents throughout the processing region with a high plasma potential. An inductively-coupled plasma formed above the substrate may provide a more controlled delivery of plasma effluents, while the capacitively-coupled plasma may develop plasma species that may cause bombardment of chamber components that may lead to sputtering. These ions and other particles may extend beyond the substrate surface, and may extend beyond the surface of the substrate support as well.

Some processing chambers include a pumping system coupled downstream of the substrate support. Often, a plenum region is formed about the substrate support allowing effluent and precursor flow about the support and out from the chamber. Because of this additional space about the substrate support, plasma species may also flow around and below the pedestal. Chamber coatings may not extend fully through these return paths from the chamber. Plasma species that are allowed to enter these regions may bombard surfaces and components causing sputtering. This can erode chamber components over time, and can also cause metal contamination on substrates being worked due to flow patterns within the chamber. Some conventional technologies include a plasma filter around the substrate support that extends to the chamber walls. Although these filters may affect effluent flow, they may not sufficiently eliminate plasma species to limit metal contamination in advanced technologies. Additionally, these screens may be fully immobile, and may not allow translation of the substrate support during processing operations. Finally, because the filter is often a conductive component, the filter cannot be used with processing systems generating a bias plasma, because the filter would not be held at electrical ground.

The present technology overcomes these issues by using a plasma screen that may fully eliminate plasma effluents and ionic species from the chamber processing region, allowing enhanced protection against metal contamination from sputtering. The screen according to the present technology is specifically incorporated to be used with a substrate support that is used to generate a bias plasma by maintaining the screen electrically isolated from the plasma generating electrodes of the substrate support. Additionally, plasma screens according to the present technology may be incorporated to allow movement of the substrate support without creating an amount of spacing preventing adequate elimination of plasma species.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone.

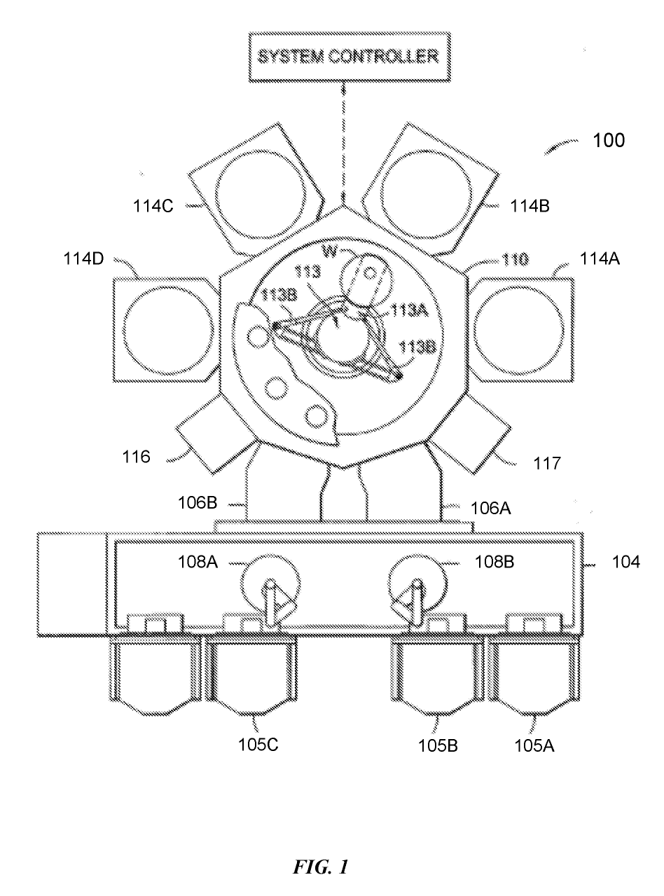

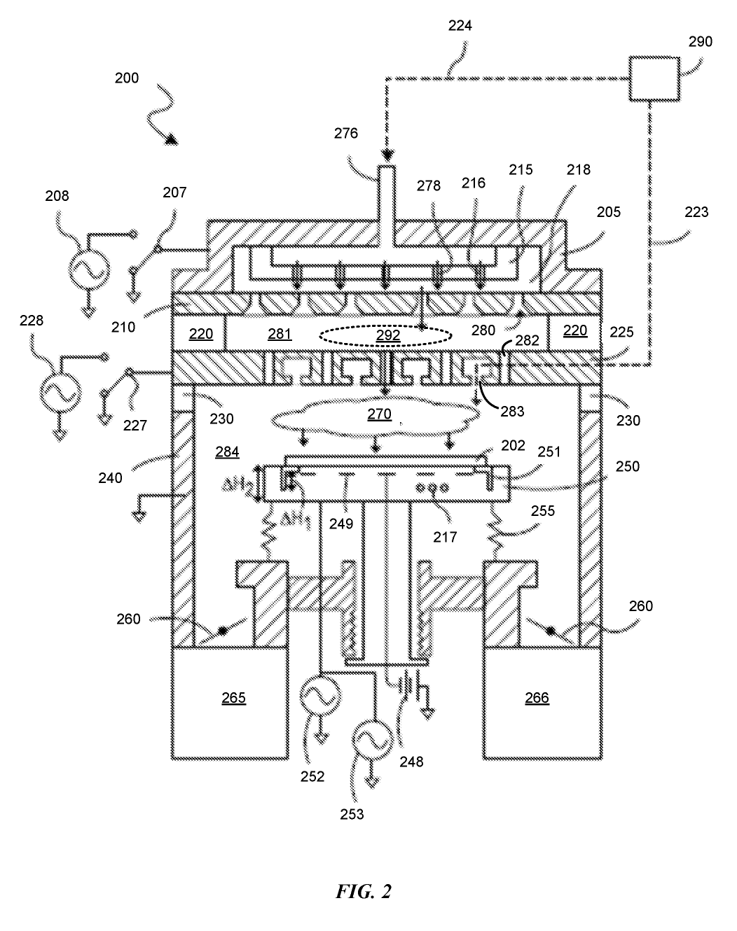

FIG. 1 shows a top plan view of one embodiment of a processing system 100 of deposition, etching, baking, and curing chambers according to embodiments. The processing tool 100 depicted in FIG. 1 may contain a plurality of process chambers, 114A-D, a transfer chamber 110, a service chamber 116, an integrated metrology chamber 117, and a pair of load lock chambers 106A-B. The process chambers may include structures or components similar to those described in relation to FIG. 2, as well as additional processing chambers.

To transport substrates among the chambers, the transfer chamber 110 may contain a robotic transport mechanism 113. The transport mechanism 113 may have a pair of substrate transport blades 113A attached to the distal ends of extendible arms 113B, respectively. The blades 113A may be used for carrying individual substrates to and from the process chambers. In operation, one of the substrate transport blades such as blade 113A of the transport mechanism 113 may retrieve a substrate W from one of the load lock chambers such as chambers 106A-B and carry substrate W to a first stage of processing, for example, an etching process as described below in chambers 114A-D. If the chamber is occupied, the robot may wait until the processing is complete and then remove the processed substrate from the chamber with one blade 113A and may insert a new substrate with a second blade (not shown). Once the substrate is processed, it may then be moved to a second stage of processing. For each move, the transport mechanism 113 generally may have one blade carrying a substrate and one blade empty to execute a substrate exchange. The transport mechanism 113 may wait at each chamber until an exchange can be accomplished.

Once processing is complete within the process chambers, the transport mechanism 113 may move the substrate W from the last process chamber and transport the substrate W to a cassette within the load lock chambers 106A-B. From the load lock chambers 106A-B, the substrate may move into a factory interface 104. The factory interface 104 generally may operate to transfer substrates between pod loaders 105A-D in an atmospheric pressure clean environment and the load lock chambers 106A-B. The clean environment in factory interface 104 may be generally provided through air filtration processes, such as HEPA filtration, for example. Factory interface 104 may also include a substrate orienter/aligner (not shown) that may be used to properly align the substrates prior to processing. At least one substrate robot, such as robots 108A-B, may be positioned in factory interface 104 to transport substrates between various positions/locations within factory interface 104 and to other locations in communication therewith. Robots 108A-B may be configured to travel along a track system within enclosure 104 from a first end to a second end of the factory interface 104.

The processing system 100 may further include an integrated metrology chamber 117 to provide control signals, which may provide adaptive control over any of the processes being performed in the processing chambers. The integrated metrology chamber 117 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Turning now to FIG. 2 is shown a cross-sectional view of an exemplary process chamber system 200 according to the present technology. Chamber 200 may be used, for example, in one or more of the processing chamber sections 114 of the system 100 previously discussed Generally, the etch chamber 200 may include a first capacitively-coupled plasma source to implement an ion milling operation and a second capacitively-coupled plasma source to implement an etching operation and to implement an optional deposition operation. The ion milling operation may also be called a modification operation. The chamber 200 may include grounded chamber walls 240 surrounding a chuck 250. In embodiments, the chuck 250 may be an electrostatic chuck that clamps the substrate 202 to a top surface of the chuck 250 during processing, though other clamping mechanisms as would be known may also be utilized. The chuck 250 may include an embedded heat exchanger coil 217. In the exemplary embodiment, the heat exchanger coil 217 includes one or more heat transfer fluid channels through which heat transfer fluid, such as an ethylene glycol/water mix, may be passed to control the temperature of the chuck 250 and ultimately the temperature of the substrate 202.

The chuck 250 may include a mesh 249 coupled to a high voltage DC supply 248 so that the mesh 249 may carry a DC bias potential to implement the electrostatic clamping of the substrate 202. The chuck 250 may be coupled with a first RF power source and in one such embodiment, the mesh 249 may be coupled with the first RF power source so that both the DC voltage offset and the RF voltage potentials are coupled across a thin dielectric layer on the top surface of the chuck 250. In the illustrative embodiment, the first RF power source may include a first and second RF generator 252, 253. The RF generators 252, 253 may operate at any industrially utilized frequency, however in the exemplary embodiment the RF generator 252 may operate at 60 MHz to provide advantageous directionality. Where a second RF generator 253 is also provided, the exemplary frequency may be 2 MHz.

With the chuck 250 to be RF powered, an RF return path may be provided by a first showerhead 225. The first showerhead 225 may be disposed above the chuck to distribute a first feed gas into a first chamber region 284 defined by the first showerhead 225 and the chamber wall 240. As such, the chuck 250 and the first showerhead 225 form a first RF coupled electrode pair to capacitively energize a first plasma 270 of a first feed gas within a first chamber region 284. A DC plasma bias, or RF bias, resulting from capacitive coupling of the RF powered chuck may generate an ion flux from the first plasma 270 to the substrate 202, e.g., Ar ions where the first feed gas is Ar, to provide an ion milling plasma. The first showerhead 225 may be grounded or alternately coupled with an RF source 228 having one or more generators operable at a frequency other than that of the chuck 250, e.g., 13.56 MHz or 60 MHz. In the illustrated embodiment the first showerhead 225 may be selectably coupled to ground or the RF source 228 through the relay 227 which may be automatically controlled during the etch process, for example by a controller (not shown). In disclosed embodiments, chamber 200 may not include showerhead 225 or dielectric spacer 220, and may instead include only baffle 215 and showerhead 210 described further below.

As further illustrated in the figure, the etch chamber 200 may include a pump stack capable of high throughput at low process pressures. In embodiments, at least one turbo molecular pump 265, 266 may be coupled with the first chamber region 284 through one or more gate valves 260 and disposed below the chuck 250, opposite the first showerhead 225. The turbo molecular pumps 265, 266 may be any commercially available pumps having suitable throughput and more particularly may be sized appropriately to maintain process pressures below or about 10 mTorr or below or about 5 mTorr at the desired flow rate of the first feed gas, e.g., 50 to 500 sccm of Ar where argon is the first feedgas. In the embodiment illustrated, the chuck 250 may form part of a pedestal which is centered between the two turbo pumps 265 and 266, however in alternate configurations chuck 250 may be on a pedestal cantilevered from the chamber wall 240 with a single turbo molecular pump having a center aligned with a center of the chuck 250.

Disposed above the first showerhead 225 may be a second showerhead 210. In one embodiment, during processing, the first feed gas source, for example, Argon delivered from gas distribution system 290 may be coupled with a gas inlet 276, and the first feed gas flowed through a plurality of apertures 280 extending through second showerhead 210, into the second chamber region 281, and through a plurality of apertures 282 extending through the first showerhead 225 into the first chamber region 284. An additional flow distributor or baffle 215 having apertures 278 may further distribute a first feed gas flow 216 across the diameter of the etch chamber 200 through a distribution region 218. In an alternate embodiment, the first feed gas may be flowed directly into the first chamber region 284 via apertures 283 which are isolated from the second chamber region 281 as denoted by dashed line 223.

Chamber 200 may additionally be reconfigured from the state illustrated to perform an etching operation. A secondary electrode 205 may be disposed above the first showerhead 225 with a second chamber region 281 there between. The secondary electrode 205 may further form a lid or top plate of the etch chamber 200. The secondary electrode 205 and the first showerhead 225 may be electrically isolated by a dielectric ring 220 and form a second RF coupled electrode pair to capacitively discharge a second plasma 292 of a second feed gas within the second chamber region 281. Advantageously, the second plasma 292 may not provide a significant RF bias potential on the chuck 250. At least one electrode of the second RF coupled electrode pair may be coupled with an RF source for energizing an etching plasma. The secondary electrode 205 may be electrically coupled with the second showerhead 210. In an exemplary embodiment, the first showerhead 225 may be coupled with a ground plane or floating and may be coupled to ground through a relay 227 allowing the first showerhead 225 to also be powered by the RF power source 228 during the ion milling mode of operation. Where the first showerhead 225 is grounded, an RF power source 208, having one or more RF generators operating at 13.56 MHz or 60 MHz, for example, may be coupled with the secondary electrode 205 through a relay 207 which may allow the secondary electrode 205 to also be grounded during other operational modes, such as during an ion milling operation, although the secondary electrode 205 may also be left floating if the first showerhead 225 is powered.

A second feed gas source, such as nitrogen trifluoride, and a hydrogen source, such as ammonia, may be delivered from gas distribution system 290, and coupled with the gas inlet 276 such as via dashed line 224. In this mode, the second feed gas may flow through the second showerhead 210 and may be energized in the second chamber region 281. Reactive species may then pass into the first chamber region 284 to react with the substrate 202. As further illustrated, for embodiments where the first showerhead 225 is a multi-channel showerhead, one or more feed gases may be provided to react with the reactive species generated by the second plasma 292. In one such embodiment, a water source may be coupled with the plurality of apertures 283. Additional configurations may also be based on the general illustration provided, but with various components reconfigured. For example, flow distributor or baffle 215 may be a plate similar to the second showerhead 210, and may be positioned between the secondary electrode 205 and the second showerhead 210. As any of these plates may operate as an electrode in various configurations for producing plasma, one or more annular or other shaped spacer may be positioned between one or more of these components, similar to dielectric ring 220. Second showerhead 210 may also operate as an ion suppression plate in embodiments, and may be configured to reduce, limit, or suppress the flow of ionic species through the second showerhead 210, while still allowing the flow of neutral and radical species. One or more additional showerheads or distributors may be included in the chamber between first showerhead 225 and chuck 250. Such a showerhead may take the shape or structure of any of the distribution plates or structures previously described. Also, in embodiments a remote plasma unit (not shown) may be coupled with the gas inlet to provide plasma effluents to the chamber for use in various processes.

In an embodiment, the chuck 250 may be movable along the distance H2 in a direction normal to the first showerhead 225. The chuck 250 may be on an actuated mechanism surrounded by a bellows 255, or the like, to allow the chuck 250 to move closer to or farther from the first showerhead 225 as a means of controlling heat transfer between the chuck 250 and the first showerhead 225, which may be at an elevated temperature of 80° C.-150° C., or more. As such, an etch process may be implemented by moving the chuck 250 between first and second predetermined positions relative to the first showerhead 225. Alternatively, the chuck 250 may include a lifter 251 to elevate the substrate 202 off a top surface of the chuck 250 by distance H1 to control heating by the first showerhead 225 during the etch process. In other embodiments, where the etch process is performed at a fixed temperature such as about 90-110° C. for example, chuck displacement mechanisms may be avoided. A system controller (not shown) may alternately energize the first and second plasmas 270 and 292 during the etching process by alternately powering the first and second RF coupled electrode pairs automatically.

The chamber 200 may also be reconfigured to perform a deposition operation. A plasma 292 may be generated in the second chamber region 281 by an RF discharge which may be implemented in any of the manners described for the second plasma 292. Where the first showerhead 225 is powered to generate the plasma 292 during a deposition, the first showerhead 225 may be isolated from a grounded chamber wall 240 by a dielectric spacer 230 so as to be electrically floating relative to the chamber wall. In the exemplary embodiment, an oxidizer feed gas source, such as molecular oxygen, may be delivered from gas distribution system 290, and coupled with the gas inlet 276. In embodiments where the first showerhead 225 is a multi-channel showerhead, any silicon-containing precursor, such as OMCTS for example, may be delivered from gas distribution system 290, and directed into the first chamber region 284 to react with reactive species passing through the first showerhead 225 from the plasma 292. Alternatively the silicon-containing precursor may also be flowed through the gas inlet 276 along with the oxidizer. Chamber 200 is included as a general chamber configuration that may be utilized for various operations discussed in reference to the present technology. The chamber is not to be considered limiting to the technology, but instead to aid in understanding of the processes described. Several other chambers known in the art or being developed may be utilized with the present technology including any chamber produced by Applied Materials Inc. of Santa Clara, Calif., or any chamber that may perform the techniques described in more detail below.

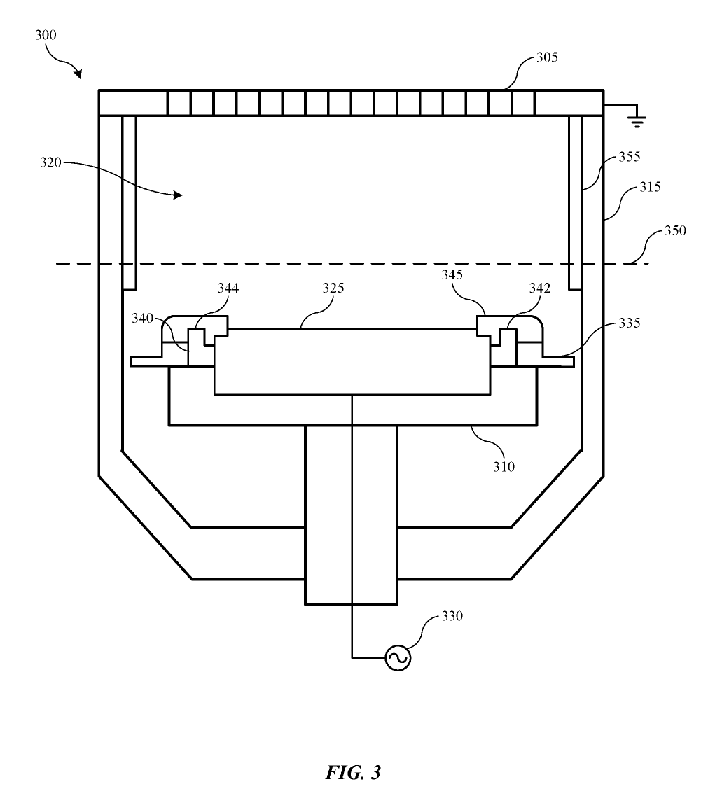

Turning to FIG. 3 is shown a partial schematic view of a processing chamber 300 according to embodiments of the present technology. FIG. 3 may include one or more components discussed above with regard to FIG. 2, and may illustrate further details relating to that chamber. The chamber 300 may be used to perform semiconductor processing operations including modification and etching as previously described. Chamber 300 may show a partial view of a processing region of a semiconductor processing system, and may not include all of the components, such as additional lid stack components previously described that are understood to be incorporated in some embodiments of chamber 300.

As noted, FIG. 3 may illustrate a portion of a processing chamber 300. The chamber 300 may include a showerhead 305, as well as a substrate support 310. Along with chamber sidewalls 315, the showerhead 305 and the substrate support 310 may define a substrate processing region 320. The substrate support may include an electrically conductive puck 325, which may be electrically coupled with a power source 330. Power source 330 may be configured to provide energy or voltage to the electrically conductive puck 325. This may form a bias plasma of a precursor within the processing region 320 of the semiconductor processing chamber 300. Ions formed within the processing region may be directed to a substrate seated on the substrate support. This may produce a modification of exposed films by damaging bonding structures, and facilitating removal in subsequent etching operations.

Chamber 300 may also include a plasma screen 335 coupled with the substrate support 310. Plasma screen 335 may be configured to substantially eliminate plasma leakage through the plasma screen, by neutralizing or eliminating plasma effluents that extend beyond the radial or lateral dimensions of the substrate support 310. While the electrically conductive puck 325 of substrate support 310 may be coupled with a power source to generate a bias plasma, plasma screen 335 may be maintained at electrical ground to allow neutralization of plasma species. Accordingly, ionic species that may otherwise bombard and sputter chamber components may be eliminated by specific configurations of plasma screens as will be discussed below. Thus, in some embodiments, the plasma screen 335 may be maintained electrically isolated from the electrically conductive puck 325 with which the power source 330 may be coupled. This isolation may be afforded by one or more components of the substrate support 310. Additionally, the plasma screen may shorten the grounding path through the electrostatic chuck compared to the chamber sidewalls 315, which may also be grounded in some embodiments.

The plasma screen 335 may be seated on a base of the substrate support 310, which may be or include a dielectric or other insulating material, which may at least partially isolate the plasma screen 335 from the electrically conductive puck 325. Additionally, isolator 340 may be positioned about an outer diameter of the electrically conductive puck 325, which may separate the puck from an inner radial edge of plasma screen 335. An edge ring 345 may be seated on the substrate support 310 and may circumscribe the electrically conductive puck 325. The edge ring may be made of quartz or some other dielectric or insulative material in embodiments, and may further insulate the plasma screen 335 from the electrically conductive puck 325. As illustrated the isolator 340 may include a flange 342 that may be seated in a channel 344 of the edge ring 345 providing stability and coupling of the components. The edge ring 345 may then be bolted to the plasma screen 335 or otherwise coupled with the screen as will be discussed further below.

The plasma screen 335 may be an annular component that may extend radially outward from the substrate support toward the chamber sidewall 315 in embodiments. In some embodiments the plasma screen 335 may not contact the chamber sidewalls. For example, a gap may be maintained between the plasma screen 335 and the chamber sidewalls 315, such as from a radial edge of the plasma screen to an inner radius of the chamber sidewall. Compared to configurations where a filter may be extended from a substrate support to a chamber sidewall, the present technology may not provide contact between the plasma screen 335 and the chamber sidewall 315, which may allow for actuation of the substrate support 310 as previously described. For example, substrate support 310 may be operable to be raised and lowered or otherwise moved as previously described along an axis to any vertical position from a first position as illustrated to a second position identified by dashed line 350.

Processing chamber 300 may also include a liner 355 positioned about an internal radius of the chamber sidewall 315. Liner 355 may extend partially along sidewall 315 in embodiments. For example, liner 355 may extend from a first position proximate showerhead 305 to a second position proximate or below dashed line 350. Plasma screen 335 may extend below a top plane of substrate support 310. Accordingly, when substrate support 310 is raised to the second position identified by dashed line 350, an exterior edge of plasma screen 335 may be positioned below a plane of dashed line 350. Liner 355 may similarly extend below dashed line 350 to a position coplanar to a top surface of an exterior edge of the plasma screen 335. In this way, the liner and plasma screen may provide a boundary to limit any effluent or precursor flow through the gap defined between an external radial edge of the plasma screen 335 and an internal radial edge of the chamber sidewalls 315.

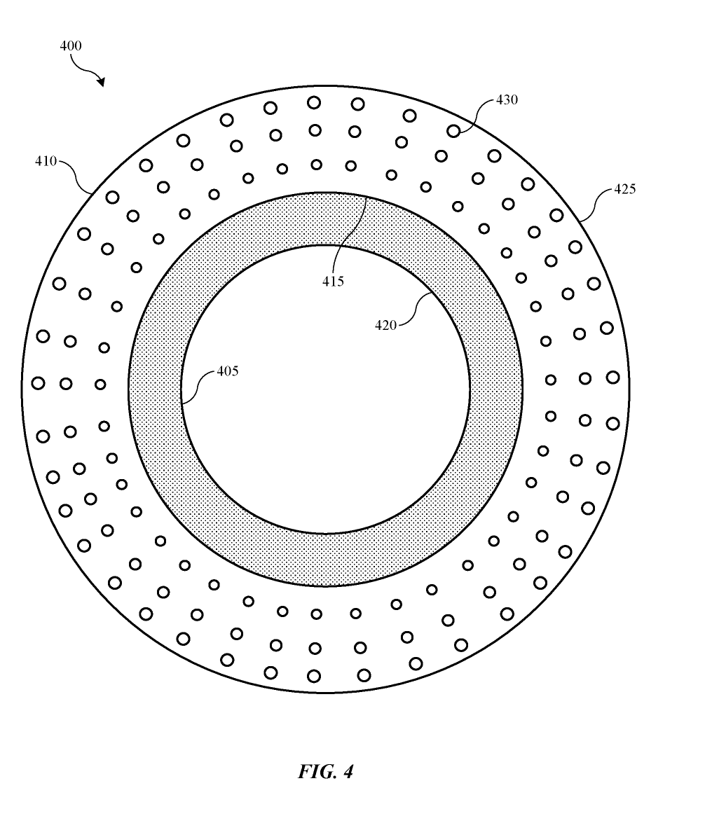

FIG. 4 shows a schematic top plan view of an exemplary plasma screen 400 according to embodiments of the present technology. Plasma screen 400 may be similar to plasma screen 335 discussed above, but may provide a view of additional features of the device. Features of plasma screen 335 and plasma screen 400 may be discussed interchangeably throughout the present disclosure. Plasma screen 400 may be an annular component in embodiments having an internal edge 405 defined about an interior radius of the plasma screen 400. Plasma screen 400 may also have an external edge 410 defined about an exterior radius of the plasma screen 400. Plasma screen 400 may be characterized by a width between the internal edge 405 and the external edge 410. Plasma screen 400 may also include an internal radius 415 defined between the interior radius and the exterior radius. The internal radius 415 may at least partially define a boundary between an interior region 420 of the plasma screen 400, and an exterior region 425 of the plasma screen 400.

Plasma screen 400 may define a plurality of apertures 430 through the plasma screen. The apertures may be included in the exterior region 425 of the plasma screen, and may not be included in the interior region 420 in some embodiments. As illustrated with plasma screen 335 of FIG. 3, the plasma screen may be coupled with an exterior edge of the substrate support 310 along an underside of the interior region 420 of the plasma screen. Additionally, edge ring 345 may be coupled with the plasma screen, and may be seated on the interior region of plasma screen 335 as illustrated. Edge ring 345 may not extend beyond internal radius 415 of the plasma screen to limit interference with the plurality of apertures 430. Accordingly, edge ring 345 may be coupled with or to plasma screen 335 allowing a secure connection between the components to limit byproducts from collecting between the two components.

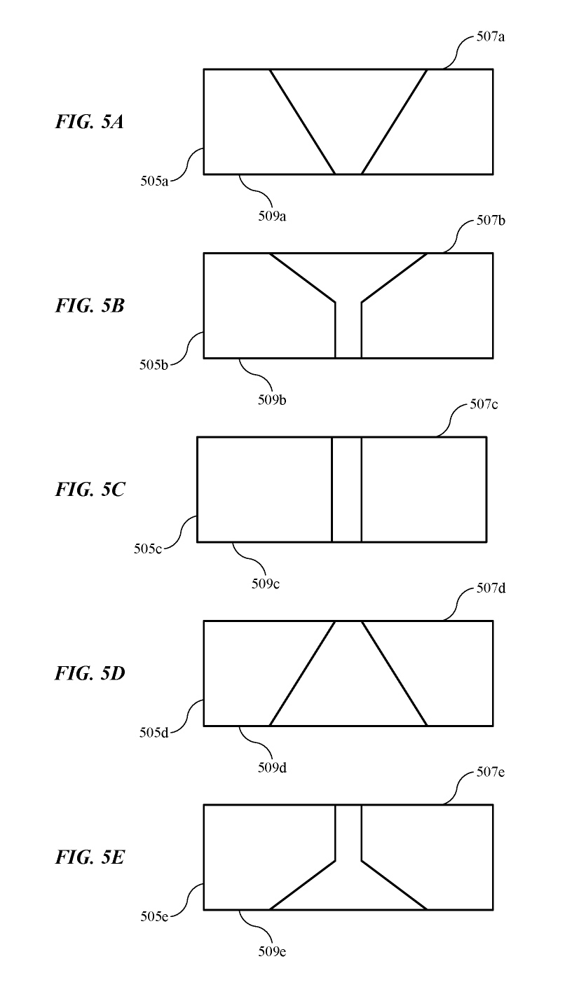

The plurality of apertures 430 may extend about the exterior region 425 of the plasma screen 400 in embodiments. As discussed below with respect to the FIG. 5 variations, each aperture of the plurality of apertures 430 may be characterized by a profile through the plasma screen. The profile as well as number of apertures and size of the apertures may produce a number of competing effects. For example, to reduce or eliminate plasma effluent transmission from the processing region, apertures of reduced diameter may be included to increase collisions allowing neutralization of the effluents. However, as the aperture size is reduced, a pressure increase through the chamber may occur. Although the pressure increase may further reduce bombardment of chamber components, the pressure increase may affect the process conditions being performed. Additionally, subsequent processes may also be affected by the increase in pressure conditions.

In some embodiments the present technology may compensate for this pressure effect by performing subsequent operations, such as a removal operation, at the lower substrate support position, which provides access to the gap region between the plasma screen and the chamber sidewalls. Regardless, plasma screens of the present technology may create a pressure increase within a processing chamber during one or more processing operations of less than or about 1 Torr, and may cause pressure increases of less than or about 500 mTorr, less than or about 250 mTorr, less than or about 100 mTorr, less than or about 90 mTorr, less than or about 80 mTorr, less than or about 70 mTorr, less than or about 60 mTorr, less than or about 50 mTorr, less than or about 40 mTorr, less than or about 30 mTorr, less than or about 25 mTorr, less than or about 20 mTorr, less than or about 15 mTorr, less than or about 10 mTorr, less than or about 5 mTorr, less than or about 2 mTorr, or may have limited effect on pressure within the processing chamber.

Apertures 430 may be characterized by a number of profiles and sizes, and may be included in a number of configurations. For example, as illustrated the apertures 430 may be included in a number of concentric rings about the exterior region 425 of the plasma screen 400. The plasma screen may include any number of rings, including 1, 2, 3, 4, 5 or more rings of apertures. The apertures may be uniform through the plasma screen in embodiments, although the apertures may be characterized by different sizes or profiles in different rings on the plasma screen. Plasma screen 400 may define any number of apertures depending on the size and distribution, including size of the plasma screen, which may be based on a chamber or substrate being modified. However, in embodiments plasma screen 400 may define greater than or about 200 apertures, greater than or about 400 apertures, greater than or about 500 apertures, greater than or about 600 apertures, greater than or about 700 apertures, greater than or about 800 apertures, greater than or about 900 apertures, greater than or about 1,000 apertures, greater than or about 1,500 apertures, or more, although the number of apertures may be limited to below or about 2,000 apertures, or less than or about 1,500 apertures to ensure elimination or neutralization of plasma effluents.

In general, the apertures may be characterized by a diameter as well as an aspect ratio, which may depend on the profile of the apertures. To provide adequate reduction or elimination of plasma effluents, each aperture may be characterized by a diameter at the narrowest cross section of less than or about 0.3 inches, and may be characterized by a diameter of less than or about 0.25 inches, less than or about 0.2 inches, less than or about 0.15 inches, less than or about 0.1 inches, less than or about 0.05 inches, or less, although in embodiments the narrowest cross section may be maintained greater than or about 0.1 inches or more to reduce an associated increase in pressure, which may affect process operations as previously described. The aspect ratio may be defined as an aperture height through the plasma screen as a ratio to the diameter at the narrowest cross section of the aperture. In embodiments, the aspect ratio may be less than or about 50:1 to reduce a pressure increase across the plasma screen. In some embodiments, the aspect ratio may be less than or about 40:1, less than or about 30:1, less than or about 20:1, less than or about 10:1, less than or about 5:1, less than or about 1:1, or less, although the aspect ratio in embodiments may be maintained greater than or about 1:1 to ensure adequate elimination of plasma effluents.

Referring to the cross-sectional view of plasma screen 335 of FIG. 3 along with top plan view of plasma screen 400, interior region 420 and exterior region 425 may be characterized by different thicknesses in embodiments of the present technology. For example, interior region 420 may be characterized by a first thickness of the plasma screen 400, while exterior region 425 may be characterized by a second thickness of the plasma screen 400. In some embodiments the second thickness may be less than the first thickness. A recessed ledge may be defined by the plasma screen 400 about internal radius 415 identifying the transition from the first thickness to the second thickness. By including an increased thickness at the interior region 420, more secure coupling may be provided between the chamber components that may limit warping. Additionally, by maintaining a reduced thickness through the exterior region 425 in which apertures 430 are included, pressure increases through the chamber caused by the plasma screen may be limited.

FIGS. 5A-5E illustrate schematic cross-sectional views of exemplary apertures that may be formed in a plasma screen according to embodiments of the present technology. The figures provide exemplary views of aperture configurations intended to illustrate possible aperture designs encompassed by embodiments of the present technology. It is to be understood that additional and alternative aperture designs may also be used. The apertures are illustrated as extending through an exemplary plasma screen 505, which may be an illustration of an exterior region 425 of plasma screens previously described. FIG. 5A illustrates an aperture configuration including a taper extending from a first surface 507a of plasma screen 505a to a second surface 509a. The first surface may be plasma-facing in embodiments, and may face a showerhead in embodiments.

FIG. 5B illustrates an additional example of a plasma screen 505b including an aperture profile including a partial taper from first surface 507b connecting to a cylindrical portion of the aperture that extends to second surface 509b. The taper portion may extend to any depth within the plasma screen before transitioning to the cylindrical portion. FIG. 5A and FIG. 5B illustrate designs that may afford improved ion elimination over other designs by providing the taper area facing the formed plasma. By providing additional surface area for interaction by ions in the plasma effluents, additional contact may be afforded that may further eliminate ionic species over other designs. In other embodiments, a straight cylindrical path may be formed as each aperture as illustrated in FIG. 5C. The aperture may extend as a cylinder directly from the first surface 507c to the second surface 509c of the plasma screen 505c.

FIG. 5D illustrates a flared aperture formation, which may illustrate an opposite configuration of FIG. 5A. For example, the illustrated aperture may flare from a first surface 507d to the second surface 509d. FIG. 5E illustrates a variation on the flared design, which may be a reverse form of the configuration of FIG. 5B. For example, the illustrated aperture may extend as a cylindrical aperture from a first surface 507e or plasma screen 505e before transitioning to a flare extending to second surface 509e. The transition may occur at any depth through the plasma screen.

In some embodiments one or more surfaces of the plasma screen may be coated to protect against sputtering or other interaction with precursors delivered through the processing chamber. For example, in some embodiments all surfaces of the plasma screen may be coated with one or more materials including oxides or other materials. For example, in some embodiments the plasma screen may be or include aluminum. The coating may include one or more materials including passivating the surface to produce anodized aluminum. Additionally, the coating may include a metal oxide, such as yttrium oxide, a plated coating, such as nickel plating, or a formed coating, such as a barrier oxide, or conformal oxide coating.

The coating may also be formed on some surfaces of the plasma screen, such as plasma-facing surfaces. For example, a first surface of plasma screen 335 facing the showerhead 305 may be coated in some embodiments while the opposite surface may not be coated. Additionally, the coating may extend over the first surface of the exterior region 425, and along the sidewall of the ledge defined at internal radius 415, while surfaces of interior region 420 may remain uncoated. The coating may also be at least partially included within apertures. For example, for apertures including a taper extending from a first surface facing the showerhead, the coating may extend along the surface of the taper extending through the aperture. These and other coatings may provide further protection to the plasma screen from plasma and other precursors used in the chambers.

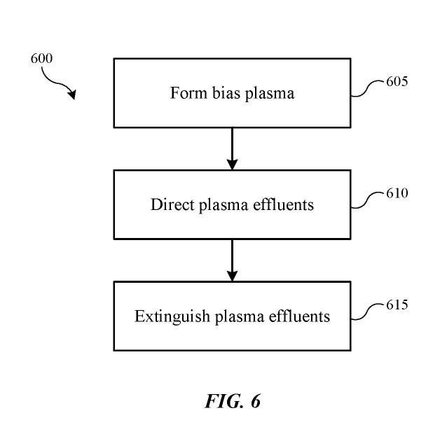

The chambers and components of the present technology may be used in a variety of processes in which plasma may be formed by a bias plasma in the processing region of the chamber. FIG. 6 illustrates exemplary operations in a method 600 according to embodiments of the present technology. The methods may include forming a bias plasma of a precursor within a processing region of a semiconductor processing chamber at operation 605. The methods may also include directing the plasma effluents by the bias plasma to a substrate positioned on a substrate support within the semiconductor processing chamber at operation 610. The methods may also include extinguishing plasma effluents with a plasma screen at operation 615. The plasma screen may be any of the plasma screen discussed throughout the present technology, and the plasma screen may be coupled about an exterior of the substrate support.

By utilizing plasma screens according to embodiments of the present technology, contamination on a substrate from sputtering of chamber components may be reduced by greater than about 5%. The reduction may be related to the materials within the processing chamber, and their location relative to the plasma. For example, as aluminum may be present as many of the components within the chamber, the present technology has been shown to reduce aluminum contamination by over 80%. Additionally, yttrium and nickel contamination have been shown to be reduced in systems including plasma screens according to the present technology by greater than 90%. Other metal contamination that may be reduced may include calcium, chromium, copper, iron, magnesium, molybdenum, sodium, nickel, potassium, yttrium, and zinc. Overall, the reduction in contamination by any of these materials may be reduced by greater than or about 10%, greater than or about 15%, greater than or about 20%, greater than or about 25%, greater than or about 30%, greater than or about 35%, greater than or about 40%, greater than or about 45%, greater than or about 50%, greater than or about 55%, greater than or about 60%, greater than or about 65%, greater than or about 70%, greater than or about 75%, greater than or about 80%, greater than or about 85%, greater than or about 95%, greater than or about 95%, or more.

When plasma screens according to the present technology are employed, the operating window for process conditions may be extended. For example, plasma power and pressure may affect the energy transferred to ionic species. As pressure is reduced, the mean free path may increase, which may result in more energy retained by ions causing increased bombardment of chamber components. Similarly, increased power may transfer more energy to plasma species. Without plasma screens, the processing conditions may be limited to higher pressure and lower plasma power within the processing region. However, when plasma screens according to the present technology are included, operating pressures may be reduced below about 20 mTorr, and may be reduced below or about 15 mTorr, below or about 10 mTorr, or below or about 5 mTorr. Additionally, the plasma power may be increased above about 1,000 W in some embodiments. Accordingly, further process tuning may be afforded by the present technology.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing chamber comprising:
a showerhead;
a substrate support;
a power source electrically coupled with the substrate support and configured to provide power to the substrate support to produce a bias plasma within a processing region defined between the showerhead and the substrate support; and
a plasma screen coupled with the substrate support and configured to substantially eliminate plasma leakage through the plasma screen, wherein the plasma screen is coupled with electrical ground.

2. The semiconductor processing chamber of claim 1, wherein the plasma screen comprises an annular component extending radially outward from the substrate support.

3. The semiconductor processing chamber of claim 2, wherein the plasma screen is characterized by a first thickness about an interior radius of the plasma screen, and wherein the plasma screen is characterized by a second thickness less than the first thickness about an exterior radius of the plasma screen.

4. The semiconductor processing chamber of claim 3, wherein the plasma screen defines a plurality of apertures through the plasma screen.

5. The semiconductor processing chamber of claim 4, wherein the plurality of apertures are defined within a region of the plasma screen characterized by the second thickness.

6. The semiconductor processing chamber of claim 4, wherein each aperture of the plurality of apertures is characterized by a profile including a taper at least partially extending through the plasma screen.

7. The semiconductor processing chamber of claim 4, wherein the plasma screen defines at least about 500 apertures through the plasma screen.

8. The semiconductor processing chamber of claim 4, wherein each aperture of the plurality of apertures is characterized by a diameter of less than or about 0.25 inches.

9. The semiconductor processing chamber of claim 1, wherein a gap is maintained between a radial edge of the plasma screen and sidewalls of the semiconductor processing chamber.

10. The semiconductor processing chamber of claim 1, wherein the plasma screen is maintained electrically isolated from an electrostatic chuck portion of the substrate support electrically coupled with the power source.

11. A semiconductor processing chamber comprising:
a chamber sidewall;
a showerhead;
a substrate support, wherein the substrate support defines a processing region of the semiconductor processing chamber with the showerhead and the chamber sidewall, wherein the substrate support comprises an electrically conductive puck, wherein the substrate support is moveable from a first vertical position within the processing region to a second vertical position within the processing region proximate the showerhead;
a power source electrically coupled with the electrically conductive puck, the power source adapted to provide energy to the electrically conductive puck to form a bias plasma within the processing region; and
a plasma screen coupled with the substrate support along a circumference of the substrate support, wherein the plasma screen extends radially outward toward the chamber sidewall, and wherein the plasma screen is maintained at electrical ground.

12. The semiconductor processing chamber of claim 11, wherein the plasma screen is characterized by an interior radius and an exterior radius, and wherein the plasma screen is characterized by an internal radius defined at a boundary between an interior region and an exterior region of the plasma screen.

13. The semiconductor processing chamber of claim 12, wherein the plasma screen defines a plurality of apertures within the exterior region of the plasma screen and extending about the plasma screen.

14. The semiconductor processing chamber of claim 12, wherein the plasma screen is coupled at an exterior edge of the substrate support along the interior region of the plasma screen.

15. The semiconductor processing chamber of claim 14, wherein the substrate support comprises an edge ring circumscribing the substrate support, wherein the edge ring is seated on the interior region of the plasma screen.

16. The semiconductor processing chamber of claim 15, wherein the edge ring is quartz.

17. The semiconductor processing chamber of claim 12, wherein the plasma screen is characterized by a first thickness within the interior region, wherein the plasma screen is characterized by a second thickness within the exterior region, and wherein the plasma screen defines a ledge at the internal radius.

18. The semiconductor processing chamber of claim 11, further comprising a liner extending along the chamber sidewall from a position proximate the showerhead to a location substantially coplanar to the plasma screen when the substrate support is in the second vertical position.

19. The semiconductor processing chamber of claim 11, wherein the plasma screen is coated on a first surface facing the showerhead.

20. A method of reducing sputtering during semiconductor processing, the method comprising:
forming a bias plasma of a precursor within a processing region of a semiconductor processing chamber;
directing plasma effluents by the bias plasma to a substrate positioned on a substrate support within the semiconductor processing chamber; and
extinguishing plasma effluents with a plasma screen coupled about an exterior of the substrate support, wherein the plasma screen reduces contamination from sputtering of chamber components by greater than about 5%.
